(19) United States
(12) Patent Application Publication
(10) Pub. No.: US 2007/0097652 A1
(43) Pub. Date: May 3, 2007

(54) Heat dissipator for a surveillance camera

(75) Inventor: Ming-Huang Huang, Taipei (TW)

Correspondence Address: BIRCH STEWART KOLASCH & BIRCH, PO BOX 747, FALLS CHURCH, VA, 22040-0747, US

(73) Assignee: CAMDEOR TECHNOLOGY CO., LTD.

(21) Appl. No.: 11/261,504

(22) Filed: Oct. 31, 2005

(51) Int. Cl. H05K 7/20

(52) U.S. Cl. 361/714

(57) ABSTRACT

A heat dissipator assembly for a surveillance camera having a casing includes an L-shaped, integrally formed heat dissipator slidably received and adapted to be in direct contact with the casing. The heat dissipator is divided into a vertical portion and a horizontal portion and the horizontal portion has multiple connecting bosses formed thereon for connection with a circuit board. A brass plate is securely mounted on a side face of the vertical portion for connection with light emitting diodes.

### BACKGROUND OF THE INVENTION

1. Field of the Invention

The present invention relates to a heat dissipator, and more particularly to a heat dissipator for a surveillance camera to facilitate heat dissipation so as to prolong the life span of the surveillance camera.

2. Description of the Related Art

A conventional surveillance camera is shown in FIG. 1, wherein the camera is provided with a casing (B), a base plate (A) mounted on a bottom face of the casing (B), a circuit board (A5) mounted on a side of the base plate (A), a connecting plate (A4) connected to the circuit board (A5) via a bolt (A1) and having multiple light emitting diodes (A3) mounted on a side face thereof, a lens (A2) mounted on the circuit board (A5) and extending out of the connecting plate (A4) and a power supply (A6) mounted on the base plate (A) via a foam material (A7).

When the conventional surveillance camera is in application, both the power supply (A6) and the LEDs (A3) generate large volume of heat which impedes normal function of the camera (A2). Besides, because the LEDs (A3) is not in direct contact with the casing (B) and the power supply (A6) is isolated from the casing (B) by the foam material (A7), heat inside the casing (B) will gradually build-up and eventually damage the camera (A2).

To overcome the shortcomings, the present invention tends to provide an improved heat dissipator to mitigate the aforementioned problems.

### SUMMARY OF THE INVENTION

The primary objective of the present invention is to provide an improved heat dissipator to be adapted for the surveillance camera so as to facilitate heat dissipation.

In one aspect of the present invention, the heat dissipator of the present invention is L-shaped and includes multiple connecting bosses formed on a top side of a horizontal portion of the heat dissipator for connection with a circuit board and a side plate securely mounted on a vertical portion of the heat dissipator for connection with the LEDs such that heat inside the surveillance camera is able to be dissipated.

Other objects, advantages and novel features of the invention will become more apparent from the following detailed description when taken in conjunction with the accompanying drawings.

### BRIEF DESCRIPTION OF THE DRAWINGS

FIG. 1 is a schematic view of a conventional surveillance camera, wherein arrows show the heat inside the casing is not well dissipated;

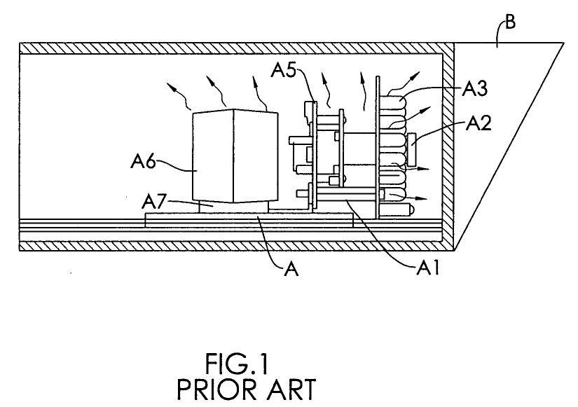

FIG. 2 is a side plan view showing the heat dissipator of the present invention;

FIG. 3 is an exploded perspective view showing that LEDs and a circuit board are to be combined with the heat dissipator of the present invention;

FIG. 4 is a perspective view showing the combination of the heat dissipator of the present invention with the LEDs and the circuit board;

FIG. 5 is a schematic perspective view showing the combination of the heat dissipator, the LEDs and the circuit board is assembled inside the casing of the surveillance camera;

FIG. 6 is a partially cross sectional view showing that the heat dissipator is in direct contact with the casing of the surveillance camera; and

FIG. 7 is a schematic view showing that heat inside the casing is well dissipated via the heat dissipator of the present invention.

### DETAILED DESCRIPTION OF THE PREFERRED EMBODIMENT

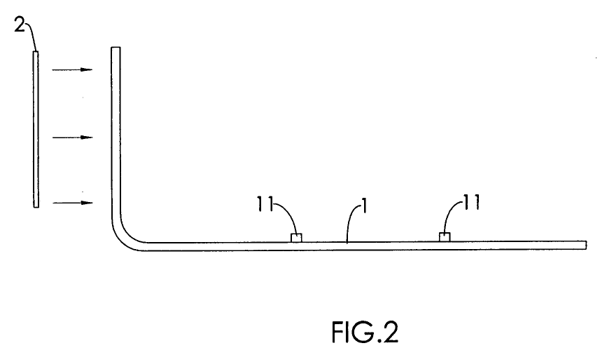

With reference to FIG. 2, it is noted that the heat dissipator (1) of the present invention is L-shaped and thus includes a vertical portion and a horizontal portion. Preferably, the heat dissipator (1) is made of aluminum.

Multiple connecting bosses (11) are formed on a top face of the horizontal portion and the vertical portion of the heat dissipator is securely engaged with a brass plate (2).

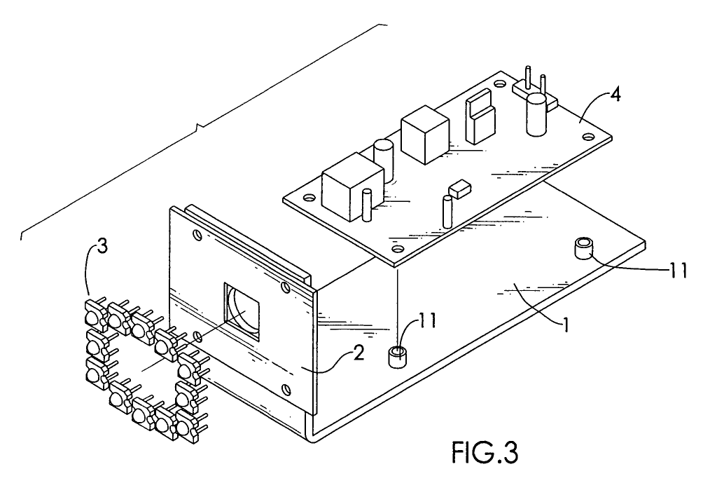

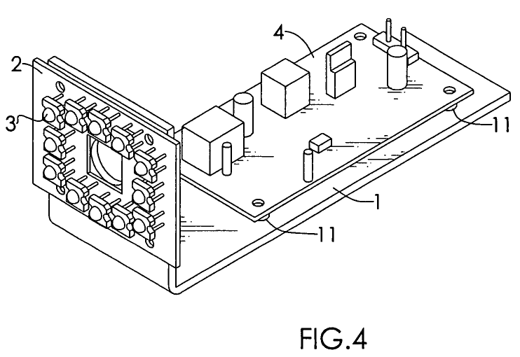

With reference to FIGS. 3 and 4, it is noted that when the heat dissipator of the present invention is to be mounted with LEDs (3) and a circuit board (4), the LEDs (3) are directly mounted on the brass plate (2) and the circuit board (4) is mounted on the top face of the horizontal portion of the heat dissipator (1) via the connecting bosses (11).

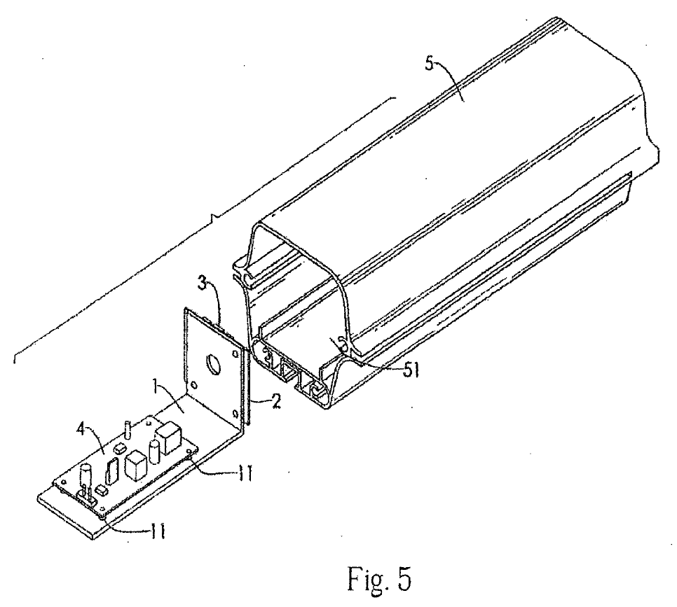

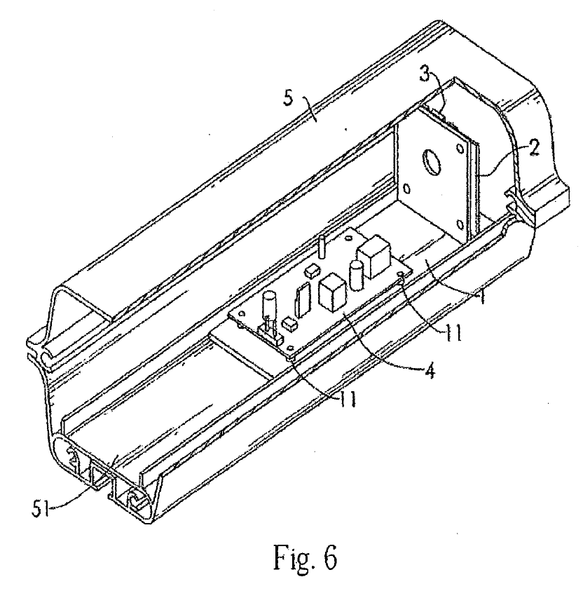

With reference to FIGS. 5 and 6, after the LEDs (3) and the circuit board (4) are respectively mounted on the vertical portion and the horizontal portion of the heat dissipator (1) of the present invention, the combination of the heat dissipator (1), the LEDs (3) and the circuit board (4) is slid into a casing (5) having a channel (51) defined therein. After the combination of the heat dissipator (1), the LEDs (3) and the circuit board (4) reaches an inner side face of the casing (5), opposed side faces of the heat dissipator (1) are in direct connect with the inner side walls of the casing (5) and a bottom face of the heat dissipator (1) is in direct contact with an inner bottom face of the casing (5) such that heat from the circuit board (4) due to components thereon and from the LEDs (3) is well dissipated from the casing (5) via heat conduction.

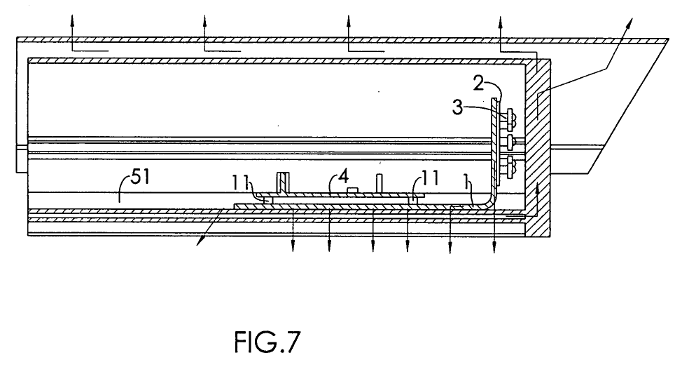

With reference to FIG. 7, it is noted that heat generated is able to be dissipated from all directions inside the casing (5) such that the life span of the surveillance camera is prolonged.

In view of the above description, it is concluded that:
1. The brass plate is able to quickly absorb heat from the LEDs so that the heat is able to be dissipated from the casing.
2. The generated heat is able to be dissipated due to direct contact between the L-shaped heat dissipator and the casing.
3. The L-shaped heat dissipator is integrally formed.
4. The L-shaped heat dissipator is vastly applicable.
5. The boss in direct contact with the power supply is able to dissipate heat from the power supply.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

1. A heat dissipator assembly for a surveillance camera having a casing, the heat dissipator comprising;
an L-shaped, integrally formed heat dissipator slidably received and adapted to be in direct contact with the casing, the heat dissipator being divided into a vertical portion and a horizontal portion, the horizontal portion having multiple connecting bosses formed thereon for connection with a circuit board, and
a flat and rectangular plate securely mounted on a side face of the vertical portion for connection with light emitting diodes for absorbing heat from the light emitting diodes.

2. The heat dissipator assembly as claimed in claim 1, wherein the plate is made of brass.

3. The heat dissipator assembly as claimed in claim 2, wherein the heat dissipator is made of aluminum.

4. The heat dissipator assembly as claimed in claim 1, wherein the plate covers a majority of the area of the vertical portion of the heat dissipator.

5. The heat dissipator assembly as claimed in claim 1, wherein the vertical portion and the horizontal portion of the heat dissipator both have a same width throughout their entire lengths.
